(19) United States
(12) Patent Application Publication
(10) Pub. No.: US 2026/0235649 A1
(43) Pub. Date: Aug. 13, 2026

(54) CURRENT SENSOR

(71) Applicant: Yazaki Corporation, Tokyo (JP)

(72) Inventors: Yoshio SUGIMOTO, Makinohara-shi (JP); Toshiaki FUKUHARA, Makinohara-shi (JP); Takaya MIWA, Makinohara-shi (JP)

(73) Assignee: Yazaki Corporation, Tokyo (JP)

(21) Appl. No.: 19/180,288

(22) Filed: Apr. 16, 2025

(30) Foreign Application Priority Data
May 21, 2024 (JP) 2024-082858

(51) Int. Cl. G01R 19/00; G01R 15/20; G01R 33/00

(52) U.S. Cl. CPC G01R 19/0092; G01R 15/202; G01R 15/207; G01R 33/0011

(57) ABSTRACT

A current sensor includes: a busbar with a second portion protruding from one end edge of a first portion; a magnetic flux concentrating plate having an orthogonal cross-section shape surrounding, in a C-shape, a middle portion of the first portion of the busbar, the orthogonal cross-section shape extending orthogonally to the busbar longitudinal direction, wherein the magnetic flux concentrating plate is configured to concentrate magnetic flux around the middle portion, the magnetic flux being generated due to a current which may flow through the busbar, wherein an opened portion of the C-shape is opened in a direction of protrusion of the second portion; and a sensor section including a Hall element which detects the current through the magnetic flux concentrated by the magnetic flux concentrating plate.

### BACKGROUND OF THE INVENTION

### Technical Field

The present invention relates to a current sensor for detecting a current from a measured object by means of a Hall element.

### BACKGROUND ART

Conventionally, current sensors are known which use a Hall element to detect a current from a measured object (see e.g. Patent Document 1). In many cases, the current sensor as described in this Patent Document 1 is configured to cause a current from a measured object to flow into a busbar, wherein the current is detected by means of a Hall element through magnetic flux which may be generated when the current flows through the busbar, wherein the Hall element is positioned in vicinity of the busbar. Furthermore, in order to concentrate the magnetic flux around the Hall element and to thus increase an accuracy of current measurement, a magnetic flux concentrating plate made of a soft magnetic material is provided which surrounds the Hall element together with a middle portion of the busbar.

### Citation List

### Patent Literature

Patent Document 1: JP 2011-232246 A

### SUMMARY OF THE INVENTION

In some cases, a busbar having a bent shape is used as the busbar for the current sensor as described above, wherein the bent busbar includes a first portion and a second portion protruding from one end edge of the first portion, the first and second portions having a belt shape. In the case of the bent busbar with the above-described magnetic flux concentrating plate, the magnetic flux concentrating plate has a higher tendency of occurrence of magnetic saturation than a magnetic flux concentrating plate used with a straight busbar, which may reduce a measurement accuracy. It would be conceivable to increase a size of the magnetic flux concentrating plate in order to suppress the magnetic saturation. However, this may result in an increased size of the sensor itself, and therefore, this is not very desirable.

Therefore, the present invention is focused on the above-described problem, and an objective of the present invention is to provide a current sensor which enables magnetic saturation of a magnetic flux concentrating plate to be suppressed by using a busbar with a bent shape while limiting increase in size.

In order to achieve the above-described objective, a current sensor includes: a busbar made of an electrically conductive metal and configured to allow a current from a measured object to flow therethrough, wherein the busbar includes a first portion having a belt shape and a second portion, wherein the second portion protrudes in a direction of protrusion from one end edge of the first portion, the direction of protrusion intersecting front and back faces of the first portion; a magnetic flux concentrating plate made of a soft magnetic material, wherein the magnetic flux concentrating plate has an orthogonal cross-section shape having a bent-plate shape surrounding, in a C-shape, a middle portion of the first portion of the busbar in a busbar longitudinal direction, the orthogonal cross-section shape extending orthogonally to the busbar longitudinal direction, wherein the magnetic flux concentrating plate is configured to concentrate magnetic flux around the middle portion, the magnetic flux being generated due to a current which may flow through the busbar, wherein an opened portion of the C-shape is opened in the direction of protrusion; and a sensor section including a Hall element for current detection, wherein the Hall element is configured to be positioned so as to be surrounded by the magnetic flux concentrating plate while being positioned between the opened portion and the middle portion so that the Hall element detects the current through the magnetic flux concentrated by the magnetic flux concentrating plate.

The current sensor as described above enables magnetic saturation of the magnetic flux concentrating plate to be suppressed by using a busbar with a bent shape while limiting increase in size.

### BRIEF DESCRIPTION OF THE DRAWINGS

FIG. 1 shows a perspective view of a current sensor according to an embodiment;

FIG. 2 shows a side view of the current sensor as shown in FIG. 1 in a direction of arrow V11 in FIG. 1;

FIG. 3 shows a cross-sectional view of the current sensor as shown in FIG. 1 along the line V12-V12 in FIG. 1;

FIG. 4 shows a perspective view of a current sensor according to a reference example for comparison to the current sensor as shown in FIGS. 1 to 3;

FIG. 5 shows a side view of the current sensor as shown in FIG. 4 in a direction of arrow V51 in FIG. 4;

FIG. 6 schematically shows how magnetic flux which may be generated when a current flows through a busbar is absorbed by a magnetic flux concentrating plate in the current sensor according to the reference example as shown in FIGS. 4 and 5;

FIG. 7 schematically shows how absorption of magnetic flux by a magnetic flux concentrating plate is suppressed in the current sensor according to the embodiment as shown in FIGS. 1 to 3, wherein the magnetic flux may be generated when a current flows through a busbar;

FIG. 8 shows a graph illustrating magnetic flux densities for the magnetic flux concentrating plates of the current sensors according to the embodiment as shown in FIGS. 1 to 3 and according to the reference example as shown in FIGS. 4 and 5, together with a magnetic flux density for a magnetic flux concentrating plate of a current sensor in the standard form with a straight busbar;

FIG. 9 shows a perspective view of the current sensor in the standard form, wherein the magnetic flux concentrating plate of this current sensor has a magnetic flux density which is shown in the graph of FIG. 8; and

FIG. 10 shows a graph illustrating that the current sensors according to the embodiment as shown in FIGS. 1 to 3, according to the reference example as shown in FIGS. 4 and 5, and the current sensor in the standard form as shown in FIG. 9 have a substantially same value of magnetic flux density at a location where a Hall element is positioned.

### DETAILED DESCRIPTION OF THE PREFERRED EMBODIMENTS

Hereinafter, a current sensor according to an embodiment will be described.

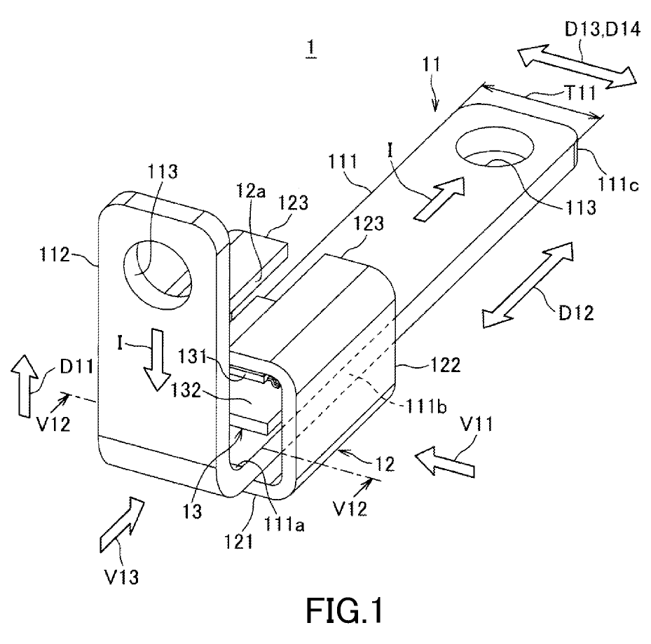

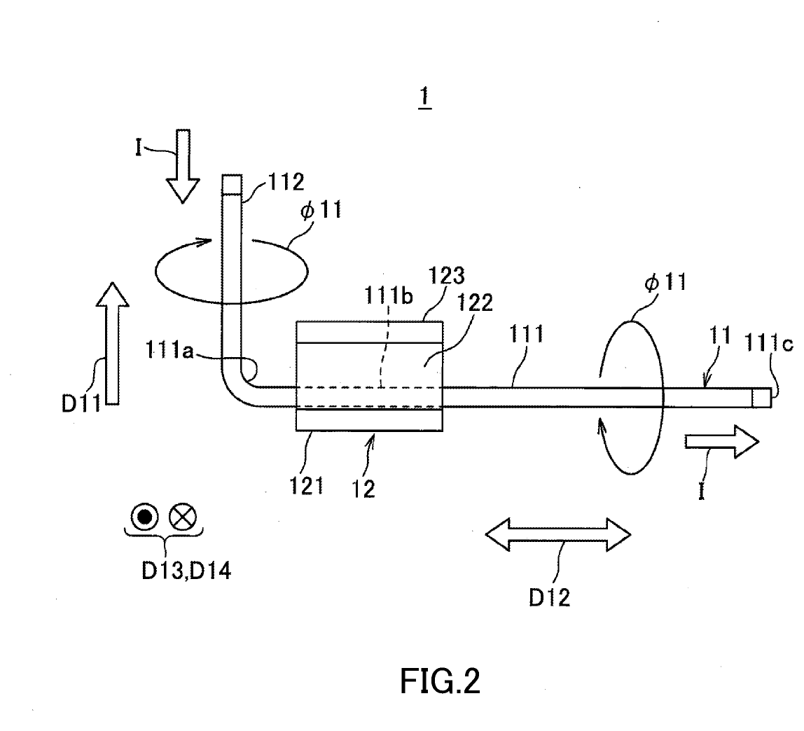

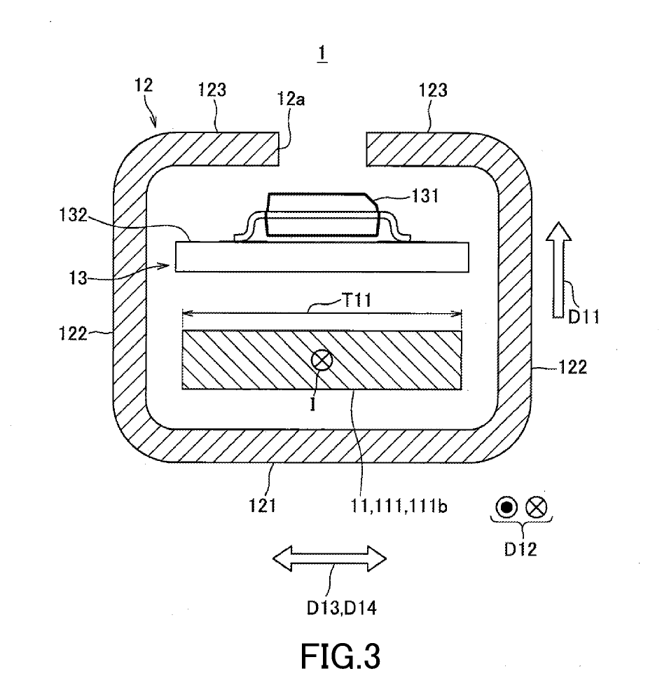

FIG. 1 shows a perspective view of a current sensor according to an embodiment. FIG. 2 shows a side view of the current sensor as shown in FIG. 1 in a direction of arrow V11 in FIG. 1. Furthermore, FIG. 3 shows a cross-sectional view of the current sensor as shown in FIG. 1 along the line V12-V12 in FIG. 1.

The current sensor 1 according to the present embodiment is configured to detect current I from the measured object by means of a Hall element 131. The current sensor 1 includes a busbar 11, a magnetic flux concentrating plate 12, and a sensor section 13.

The busbar 11 is made of an electrically conductive metal and configured to allow a current I from a measured object to flow therethrough. The busbar 11 includes a first portion 111 and a second portion 112. The first portion 111 is a belt-shaped elongated portion, and the second portion 112 is a belt-shaped short portion which protrudes in a direction of protrusion D11 from one end edge 111a of the first portion 111 in a busbar longitudinal direction D12, the direction of protrusion D11 intersecting front and back faces of the first portion 111, wherein the second portion 112 is shorter than the first portion 111. According to the present embodiment, the busbar 11 is configured as a bent member formed only by the first portion 111 and the second portion 112 to form an L-shape in a side view of the busbar 11 in an orthogonal direction (direction of arrow V11), the orthogonal direction extending orthogonally to the direction of protrusion D11 and the busbar longitudinal direction D12. Furthermore, the L-shaped busbar 11 has a through hole 113 in each of two opposite ends of the busbar 11 for connection to the measured object e.g. by screwing.

The magnetic flux concentrating plate 12 is made of a soft magnetic material, wherein the magnetic flux concentrating plate 12 has an orthogonal cross-section shape having a bent-plate shape surrounding, in a C-shape, a middle portion 111b of the first portion 111 of the busbar 11 in the busbar longitudinal direction D12, the orthogonal cross-section shape extending orthogonally to the busbar longitudinal direction D12. This magnetic flux concentrating plate 12 concentrates magnetic flux φ (FIG. 2) around the middle portion 111b of the first portion 111, the magnetic flux being generated due to a current I which may flow through the busbar 11. In addition, the magnetic flux concentrating plate 12 is positioned with respect to the middle portion 111b of the first portion 111 so that an opened portion 12a of the C-shape is opened in the direction of protrusion D11 of the second portion 112. Moreover, the magnetic flux concentrating plate 12 is positioned at the one end edge 111a of the first portion 111 and at a location of another end edge 111c of the first portion 111 opposite to the one end edge 111a in the busbar longitudinal direction D12, the second portion 112 protruding from the one end edge 111a of the first portion 111, wherein the location is a location of another end edge 111c which is closest to the one end edge 111a. More specifically, the magnetic flux concentrating plate 12 is positioned closer to the one end edge 111a than a middle of the first portion 111 in the busbar longitudinal direction D12.

According to the present embodiment, the magnetic flux concentrating plate 12 is a rectangular tubular bent member, wherein the magnetic flux concentrating plate 1 is partially cutout in a peripheral wall of the magnetic flux concentrating plate 12 to form the opened portion 12a. The magnetic flux concentrating plate 12 according to the present embodiment includes a bottom plate section 121, a pair of arm plate sections 122, and a pair of top plate sections 123.

The bottom plate section 121 of the magnetic flux concentrating plate 12 is facing a face of front and back faces of the middle portion 111b of the first portion 111 opposite to a side of the middle portion with the Hall element 131 positioned thereon. This bottom plate section 121 is a rectangular plate-shaped portion which has a larger extension in a concentrating plate longitudinal direction D14 than a width dimension T11 of the first portion 111, the concentrating plate longitudinal direction D14 extending along a busbar width direction D13 of the first portion 111. The pair of arm plate sections 122 is a pair of rectangular plate-shaped portions which protrudes in the direction of protrusion D11 of the second portion 112 from two opposite end edges of the bottom plate section 121 in the concentrating plate longitudinal direction D14. The pair of top plate sections 123 is a pair of rectangular plate-shaped portions which each extend along the concentrating plate longitudinal direction D14 from one of protrusion end edges of the pair of arm plate sections 122 so as to face a face of the middle portion 111b of the first portion 111 with the Hall element 131 positioned thereon. In addition, extension end edges of the pair of top plate sections 123 are spaced from each other to form the opened portion 12a of the magnetic flux concentrating plate 12 together.

The sensor section 13 includes the Hall element 131 for current detection, wherein the Hall element 131 is positioned so as to be surrounded by the magnetic flux concentrating plate 12 while being positioned between the opened portion 12a and the middle portion 111b of the first portion 111. In this case, the Hall element 131 is positioned closer to the opened portion 12a of the magnetic flux concentrating plate 12 than the first portion 111 in the direction of protrusion D11 of the second portion 112. The sensor section 13 uses the Hall element 131 to detect the current I through the magnetic flux φ11 concentrated by the magnetic flux concentrating plate 12. This sensor section 13 includes the Hall element 131 and a sensor board 132. The Hall element 131 is a rectangular flat element that detects the current I flowing through the busbar 11 via the magnetic flux φ11. The sensor board 132 is a rectangular flat circuit board with the Hall element 131 mounted thereon, wherein e.g. a circuit for amplification of a detection result obtained by the Hall element 131 is formed on the sensor board 132.

Here, a reference example for comparison to the current sensor 1 according to the present embodiment will be described before continuing explanation of the current sensor 1.

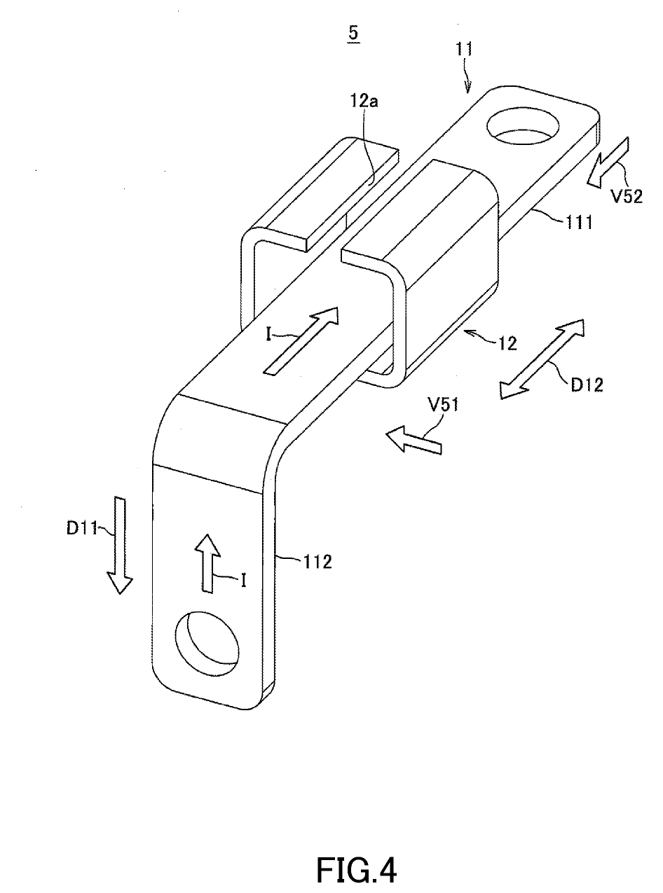

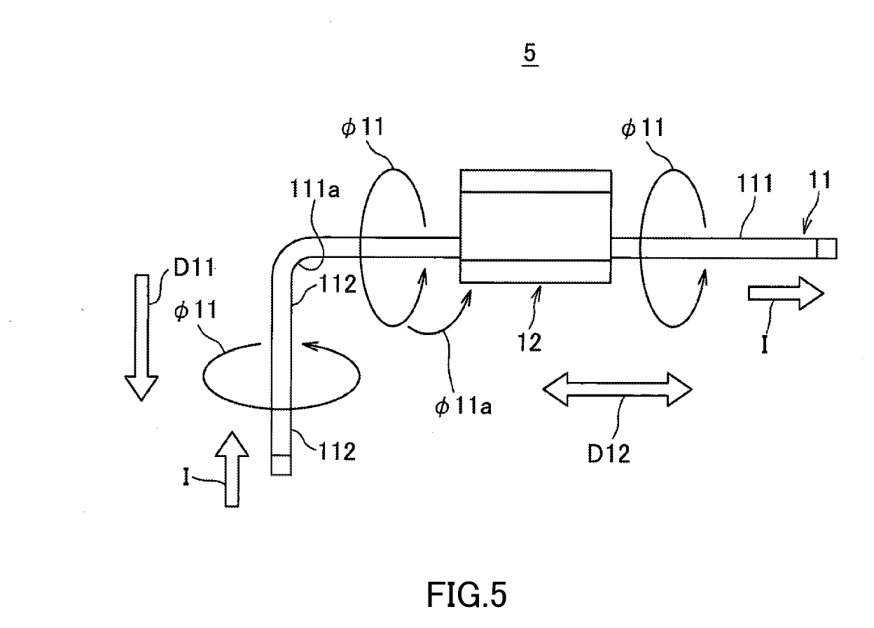

FIG. 4 shows a perspective view of a current sensor according to a reference example for comparison to the current sensor as shown in FIGS. 1 to 3. FIG. 5 shows a side view of the current sensor as shown in FIG. 4 in a direction of arrow V51 in FIG. 4. It is to be noted that in FIGS. 4 and 5, only elements which are equivalent to those as shown in FIGS. 1 to 3 and necessary for explanation are designated with same reference signs as those shown in FIGS. 1 to 3. In addition, the current sensor 5 according to the reference example includes a same sensor section as the sensor section 13 shown in FIGS. 1 and 3. However, this sensor section is omitted in FIG. 4.

Although the current sensor 5 according to the reference example as shown in FIGS. 4 and 5 includes a similar L-shaped busbar 11 and a similar C-shaped magnetic flux concentrating plate 12 as those shown in FIGS. 1 to 3, the magnetic flux concentrating plate 12 is positioned with respect to the busbar 11 in a different manner. The magnetic flux concentrating plate 12 of the current sensor 5 according to the reference example is positioned such that the opened portion 12a of the C-shape is opened in a direction opposite to the direction of protrusion D11 of the second portion 112. Furthermore, the magnetic flux concentrating plate 12 of the current sensor 5 according to the reference example is positioned in a middle of the first portion 111 in the busbar longitudinal direction D12. It is to be noted that FIGS. 4 and 5 show the current sensor 5 according to the reference example to be positioned with an inversed orientation of the current sensor shown in FIGS. 1 and 2, namely the direction of protrusion D11 of the second portion 112 is shown to be oriented downward in FIGS. 4 and 5.

In the current sensor 5 according to the reference example, magnetic flux φ which may be generated when a current I flows through the busbar 11 is absorbed by the magnetic flux concentrating plate 12 in the following manner:

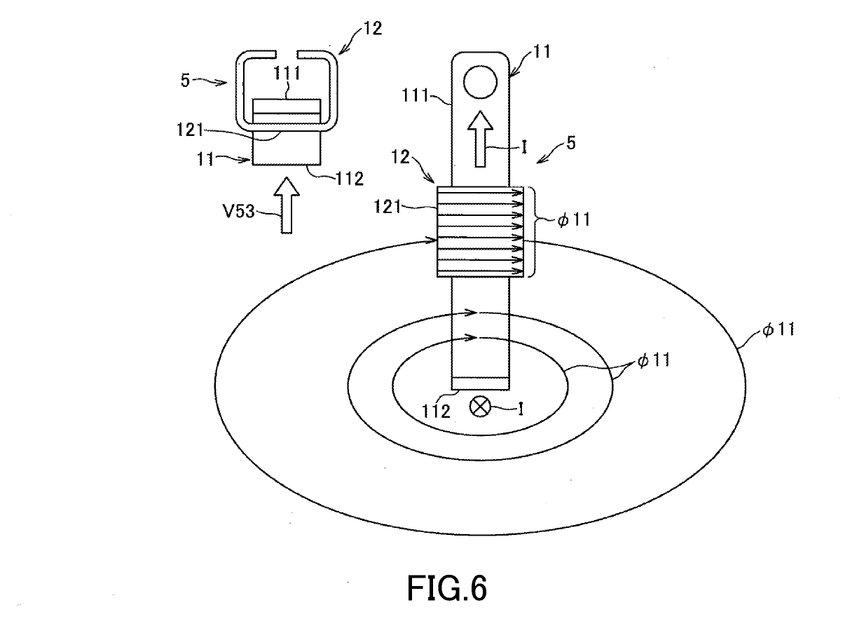

FIG. 6 schematically shows how magnetic flux which may be generated when a current flows through a busbar is absorbed by a magnetic flux concentrating plate in the current sensor according to the reference example as shown in FIGS. 4 and 5. This FIG. 6 shows the current sensor 5 according to the reference example in a plan view in the direction V52 shown in FIG. 4 and in a plan view in the direction V53 shown in FIG. 6. The direction V53 in FIG. 6 is a direction in which the current sensor 5 according to the reference example is viewed from a side of the busbar 11 for protrusion of the second portion 112.

The magnetic flux concentrating plate 12 of the current sensor 5 according to the reference example is positioned so that the bottom plate section 121 faces a protruding side of the second portion 112. When a current I flows through the busbar 11 in the above arrangement, the bottom plate section 121 of the magnetic flux concentrating plate 12 is positioned in magnetic flux φ11 generated around each of the first portion 111 and the second portion 112. In the C-shaped magnetic flux concentrating plate 12, the uninterrupted bottom plate section 121 then absorbs the magnetic flux φ11. Accordingly, the magnetic flux φ11 around each of the first portion 111 and the second portion 112 is absorbed together by the bottom plate section 121, which increases a magnetic flux density in the magnetic flux concentrating plate 12.

As shown in FIG. 5, the magnetic flux concentrating plate 12 of the current sensor 5 according to the reference example is positioned in the middle of the first portion 111 in the busbar longitudinal direction D12. As a result, the bottom plate section 121 also absorbs magnetic flux φ11a, part of the magnetic flux φ11 generated around the first portion 111 surrounded by the magnetic flux concentrating plate 12, which comes from a side of the first portion 111 including the one end edge 111a with the second portion 112 protruding therefrom, which further increases the magnetic flux density in the magnetic flux concentrating plate 12.

In contrast to the current sensor 5 according to the reference example, the current sensor 1 according to the embodiment as shown in FIGS. 1 to 3 is provided such that absorption of the magnetic flux φ11 by the magnetic flux concentrating plate 12 is suppressed as described below when a current I flows through the busbar 11.

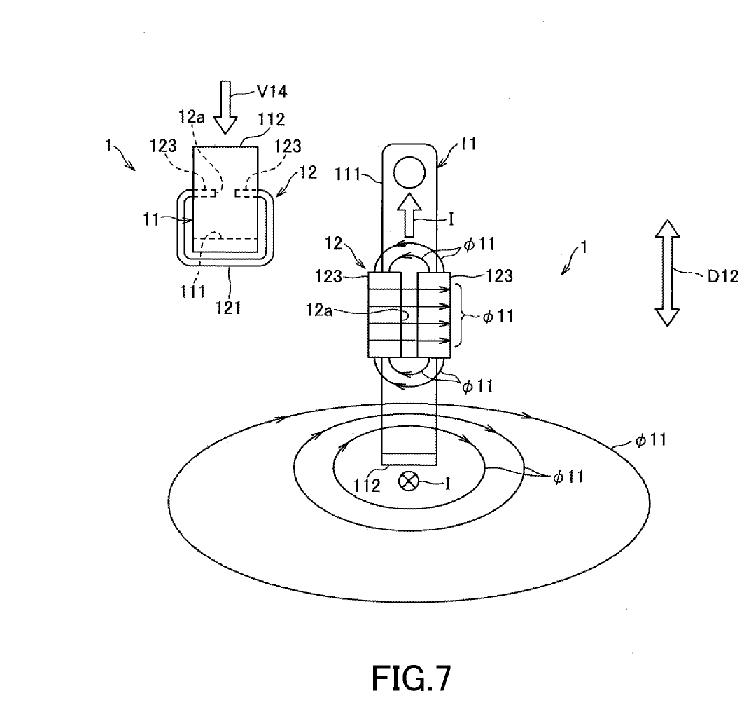

FIG. 7 schematically shows how absorption of magnetic flux by a magnetic flux concentrating plate is suppressed in the current sensor according to the embodiment as shown in FIGS. 1 to 3, wherein the magnetic flux may be generated when a current flows through a busbar. This FIG. 7 shows the current sensor 1 according to the present embodiment in a plan view in the direction V13 in FIG. 1 and in a plan view in the direction V14 in FIG. 7. The direction V14 in FIG. 7 is a direction in which the current sensor 1 according to the present embodiment is viewed from a side of the busbar 11 for protrusion of the second portion 112. It is to be noted that for ease of comparison to the current sensor 5 according to the embodiment as shown in FIG. 6, this FIG. 7 shows the magnetic flux concentrating plate 12 as being positioned in the middle of the first portion 111 in the busbar longitudinal direction D12.

The magnetic flux concentrating plate 12 of the current sensor 1 according to the present embodiment is positioned so that the opened portion 12a between the pair of top plate section 123 faces a protruding side of the second portion 112. When a current I flows through the busbar 11 in the above arrangement, the opened portion 12a of the magnetic flux concentrating plate 12 is positioned in magnetic flux φ11 generated around each of the first portion 111 and the second portion 112. In the C-shaped magnetic flux concentrating plate 12, the bottom plate section 121 then faces the opened portion 12a and absorbs the magnetic flux φ11 as described above while a side of the magnetic flux concentrating plate 12 including the opened portion 12a discharges the magnetic flux φ11. Then, the magnetic flux φ11 discharged through the side of the magnetic flux concentrating plate 12 including the opened portion 12a blocks the magnetic flux φ11 around the second portion 112 so that it is prevented from reaching the magnetic flux concentrating plate 12. Even if the magnetic flux φ11 around the second portion 112 is absorbed in the side of the magnetic flux concentrating plate 12 including the opened portion 12a, the magnetic flux φ11 will be discharged through this side. As a result, the absorption of the magnetic flux φ11 around the second portion 112 by the magnetic flux concentrating plate 12 is suppressed, thereby reducing the magnetic flux density in the magnetic flux concentrating plate 12 by a corresponding amount.

Furthermore, as shown in FIGS. 1 and 2, the magnetic flux concentrating plate 12 of the current sensor 1 according to the present embodiment is positioned at a location which is close to the one end edge 111a of two opposite end edges of the first portion 111 in the busbar longitudinal direction D12 from which the second portion 112 protrudes. This results in suppression of absorption of part of the magnetic flux φ11 through the one end edge 111a, the magnetic flux φ11 being generated around the first portion 111, thereby further reducing the magnetic flux density in the magnetic flux concentrating plate 12 by a corresponding amount.

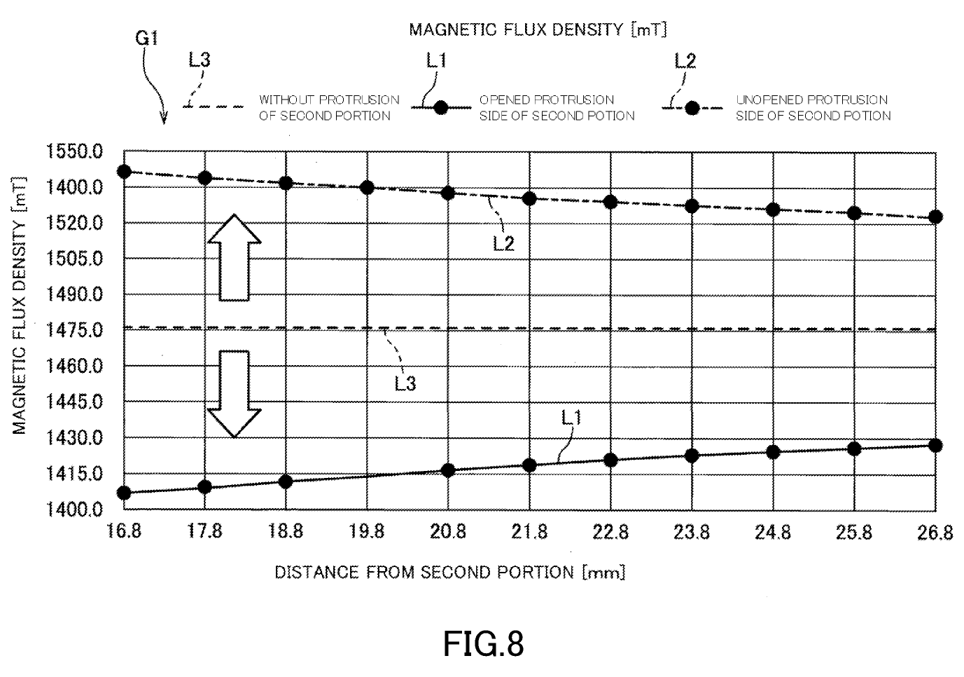

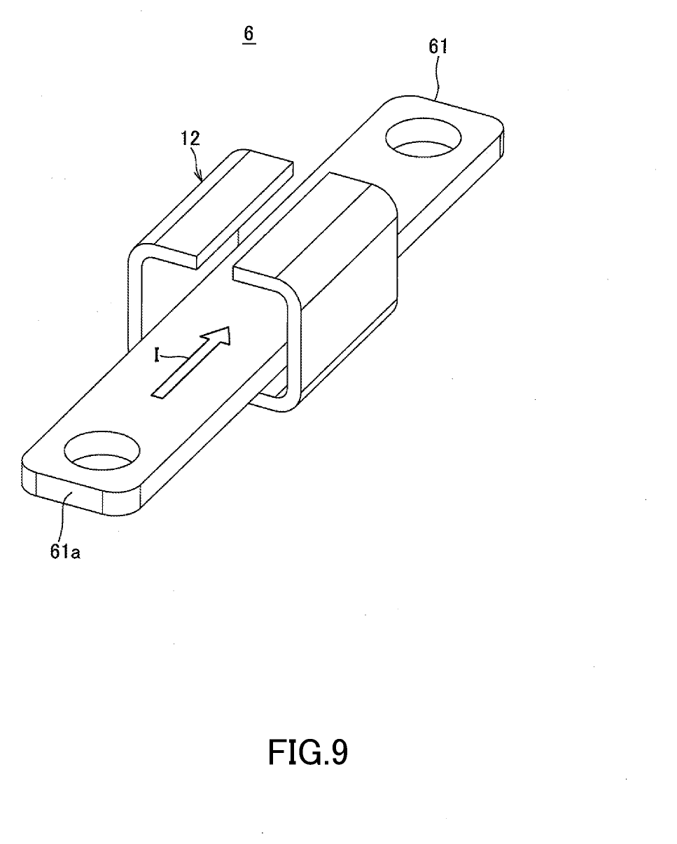

FIG. 8 shows a graph illustrating magnetic flux densities for the magnetic flux concentrating plates of the current sensors according to the embodiment as shown in FIGS. 1 to 3 and according to the reference example as shown in FIGS. 4 and 5, together with a magnetic flux density for a magnetic flux concentrating plate of a current sensor in the standard form with a straight busbar. FIG. 9 shows a perspective view of the current sensor in the standard form, wherein the magnetic flux concentrating plate of this current sensor has a magnetic flux density which is shown in the graph of FIG. 8. It is to be noted that in FIG. 9, only elements which are equivalent to those as shown in FIGS. 1 to 5 and necessary for explanation are designated with same reference signs as those shown in FIGS. 1 to 5. In addition, the current sensor 6 in the standard form includes a same sensor section as the sensor section 13 shown in FIGS. 1 and 3. However, this sensor section is omitted in FIG. 9.

First, the current sensor 6 in the standard form as shown in FIG. 9 will be described. The current sensor 6 in this standard form includes a busbar 61 which allows a current I from a measured object to flow into the busbar 61, wherein the busbar 61 has a simple straight shape unlike the L-shaped busbar 11 as shown in FIGS. 1 to 5. A magnetic flux concentrating plate 12 surrounding this straight busbar 61 is C-shaped, similarly to that shown in FIGS. 1 to 5.

Comparing the magnetic flux densities in the magnetic flux concentrating plates 12 of the current sensor 6 in the standard form, the current sensor 1 according to the aforementioned embodiment, and the current sensor 5 according to the aforementioned reference example, a result as shown in a graph G1 in FIG. 8 is obtained. The graph G1 of FIG. 8 shows the magnetic flux density in the magnetic flux concentrating plate 12 in each of the forms by means of a change in the magnetic flux density which is obtained by increasing a distance between the magnetic flux concentrating plate 12 and the one end edge 111a from which the second portion 112 protrudes. For the current sensor 6 in the standard form with the straight busbar 61, a change in the magnetic flux density is shown which is obtained by increasing a distance between the magnetic flux concentrating plate 12 and the one end edge 61a of the busbar 61. In the graph G1, a distance to the magnetic flux concentrating plate 12 [mm] and the magnetic flux density of the magnetic flux concentrating plate 12 [mT] are shown along the horizontal axis and vertical axis, respectively. The magnetic flux density in the current sensor 1 according to the embodiment and the magnetic flux density in the current sensor 5 according to the reference example are shown by means of a solid line L1 and a dash-dotted line L2, respectively. Additionally, the magnetic flux density of the current sensor 6 in the standard form is shown by a dashed line L3.

Comparison of the magnetic flux densities for the above-described three types of forms in graph G1 of FIG. 8 shows that the magnetic flux density is limited at most in the current sensor 1 according to the embodiment with the opened portion 12a of the magnetic flux concentrating plate 12 facing the protruding side of the second portion 112. On the other hand, in the reference example current sensor 5 with the opened portion 12a being oriented away from the protruding side of the second portion 112, the highest magnetic flux density is present at the absorbing bottom plate section 121 as described above because absorption of magnetic flux around the second portion 112 occurs in the bottom plate section 121. The current sensor 6 in the standard form without protrusion of the second portion 112 has a moderate magnetic flux density between those of the embodiment and the reference example.

Furthermore, the magnetic flux density in the current sensor 1 according to the embodiment is gradually increased in a direction in which a distance between the magnetic flux concentrating plate 12 and the one end edge 111a with the second portion 112 protruding therefrom is increased. This is because an increased magnetic flux φ11 is absorbed by the bottom plate section 121 from an area between the one end edge 111a of the first portion 111 and the magnetic flux concentrating plate 12. On the other hand, the magnetic flux density in the current sensor 5 according to the reference example is gradually decreased in a direction in which a distance between the magnetic flux concentrating plate 12 and the one end edge 111a is increased. This is because the magnetic flux φ11 absorbed from the second portion 112 is decreased by an amount exceeding an amount by which the magnetic flux φ11 absorbed from the first portion 111 is increased. The magnetic flux density in the current sensor 6 in the standard form has a substantially constant value regardless of the position of the magnetic flux concentrating plate 12.

While three types of forms including the embodiment differ from each other in the magnetic flux density in the magnetic flux concentrating plate 12 as described above, the magnetic flux densities have a substantially same value of magnetic flux density at a location where a Hall element 131 for magnetic flux detection is positioned, as described below.

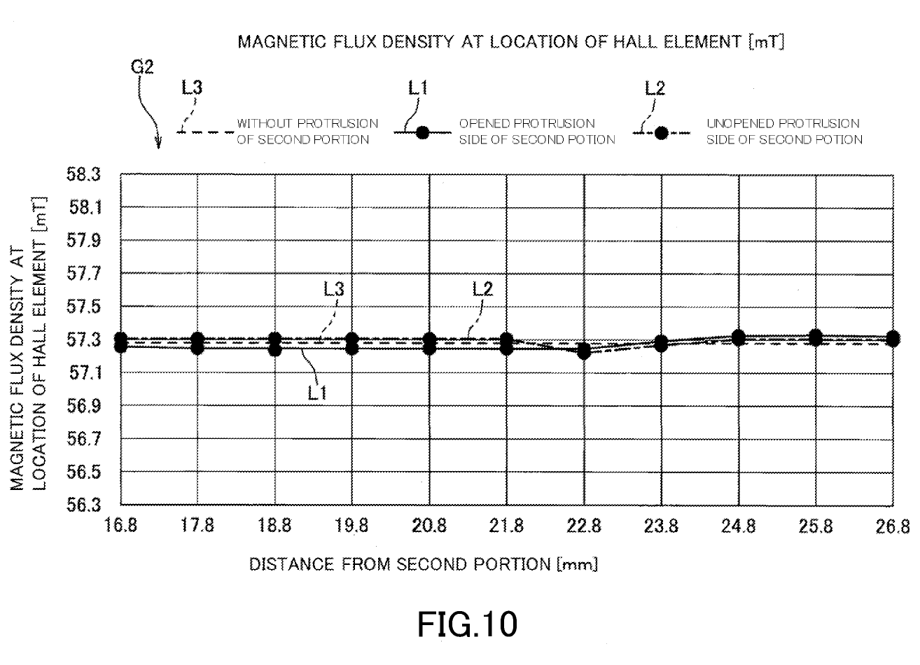

FIG. 10 shows a diagram illustrating that the current sensors according to the embodiment as shown in FIGS. 1 to 3, according to the reference example as shown in FIGS. 4 and 5, and the current sensor in the standard form as shown in FIG. 9 have a substantially same value of the magnetic flux density at a location where the Hall element is positioned. Also in the graph G2 of FIG. 10, a distance to the magnetic flux concentrating plate 12 [mm] is shown along the horizontal axis. On the other hand, the magnetic flux density at the location where the Hall element 131 is positioned [mT] is shown along the vertical axis. The magnetic flux density in the current sensor 1 according to the embodiment and the magnetic flux density in the current sensor 5 according to the reference example are shown by means of a solid line L1 and a dash-dotted line L2, respectively. Additionally, the magnetic flux density in the current sensor 6 in the standard form is shown by a dashed line L3.

As can be seen from comparison of the magnetic flux densities of the three types of forms as shown in the graph G2 of FIG. 10, the current sensors 1 and 5 according to the embodiment, according to the reference example as well as the current sensor 6 in the standard form have a substantially same value of the magnetic flux density at the location where the Hall element 131 is positioned. This means that the current sensor 1 according to the embodiment ensures a sufficiently large magnetic flux for measurement of the current detected by the Hall element 131 while suppressing the magnetic flux density of the magnetic flux concentrating plate 12 to a smaller amount than the other forms, wherein the magnetic flux is same as that in the other forms.

As described above, the current sensor 1 according to the embodiment as shown in FIGS. 1 to 3 provides the following effects: According to the present embodiment, the C-shaped magnetic flux concentrating plate 12 is arranged to surround the middle portion 111b of the first portion 111 of the bent-shaped busbar 11, wherein the opened portion 12a of the C-shape is opened in the direction of protrusion D11 of the second portion 112. A side of the C-shaped magnetic flux concentrating plate 12 facing the opened portion 12a absorbs the magnetic flux φ11 while a side of the magnetic flux concentrating plate 12 including the opened portion 12a discharges the magnetic flux φ11. Since the magnetic flux concentrating plate 12 is positioned so that the opened portion 12a is oriented in the direction of protrusion D11 of the second portion 112, this makes it difficult to absorb the magnetic flux φ11 by the magnetic flux concentrating plate 12, wherein the magnetic flux φ11 has been generated around the second portion 112, whereby magnetic saturation of the magnetic flux concentrating plate 12 is suppressed. In this manner, appropriate positioning of the C-shaped magnetic flux concentrating plate 12 may enable magnetic saturation in the case of using a bent-shaped busbar 11 to be suppressed, whereby the need for increase in a size of the magnetic flux concentrating plate 12 is eliminated, and thus, increase in a size of the current sensor 1 is suppressed. In other words, the present embodiment enables magnetic saturation of the magnetic flux concentrating plate 12 to be suppressed by using a busbar 11 with a bent shape while limiting increase in size.

According to the present embodiment, the busbar 11 is an L-shaped member, and the magnetic flux concentrating plate 12 is positioned at the one end edge 111a of the first portion 111 and at a location of another end edge 111c of the first portion 111 opposite to the one end edge 111a, the second portion 112 protruding from the one end edge 111a of the first portion 111, wherein the location is a location of another end edge 111c which is closest to the one end edge 111a. With this configuration, absorption of magnetic flux φ11, part of the magnetic flux φ11 generated around the first portion 111 surrounded by the magnetic flux concentrating plate 12, is suppressed, which comes from a side of the first portion 111 including the one end edge 111a with the second portion 112 protruding therefrom. This results in further suppression of the magnetic saturation of the magnetic flux concentrating plate 12.

Furthermore, the magnetic flux concentrating plate 12 according to the present embodiment is positioned closer to the one end edge 111a than the middle of the first portion 111. With this arrangement, a distance between the one end edge 111a of the first portion 111 and the magnetic flux concentrating plate 12 is further reduced, which results in suppression of the magnetic flux φ11 from a side of the first portion 111 including the one end edge 111a first portion 111, which results in further suppression of the magnetic saturation of the magnetic flux concentrating plate 12.

In addition, the magnetic flux concentrating plate 12 according to the present embodiment includes the bottom plate section 121, the pair of arm plate sections 122, and the pair of top plate sections 123. This configuration enables a distance between an inner surface of the magnetic flux concentrating plate 12 and the first portion 111 to be reduced as compared to a C-shaped magnetic flux concentrating plate formed by a hollow cylinder with a partially cut-out circumferential wall, which results in further suppression of increase in size of the magnetic flux concentrating plate 12.

Furthermore, the Hall element 131 according to the present embodiment is positioned closer to the opened portion 12a of the magnetic flux concentrating plate 12 than the first portion 111 in the direction of protrusion D11 of the second portion 112. With this configuration, the Hall element 131 is positioned in an area through which a large amount of magnetic flux φ11 emitted from the magnetic flux concentrating plate 12 on its side including the opened portion 12a passes. This may result in an increased sensitivity for current measurement by the Hall element 131 via the magnetic flux φ11.

It is to be noted that the above-described embodiment merely shows a representative form of a current sensor. The current sensor is not limited thereto, but may be modified and implemented in various manners.

For example, as an example of the current sensor, the above-described embodiment shows the current sensor 1 including the sensor section 13, wherein the sensor section 13 is fixed with the Hall element 131 being positioned relative to the busbar 11, and no specific fixture method is specified for fixing the sensor section 13. However, a fixture method for the sensor section in the current sensor is not limited to a specific one, but any fixture method may be employed.

Furthermore, as an example of the current sensor, the above-described embodiment shows the current sensor 1 including the busbar 11 and the magnetic flux concentrating plate 12, wherein each of them are formed by a bent member. However, the current sensor is not limited thereto. Namely, as the busbar and/or the magnetic flux concentrating plate for the current sensor, a member may be employed which is e.g. processed by means of cutting and/or formed by welding a plurality of metal parts together, wherein any processing method may be used for the busbar and magnetic flux concentrating plate.

Moreover, as an example of the current sensor, the above-described embodiment shows the current sensor 1 including the magnetic flux concentrating plate 12 which is in the vicinity of the one end edge 111a of the first portion 111 of the L-shaped busbar 11, wherein the second portion 112 of the L-shaped busbar 11 protrudes from the one end edge 111a. However, the current sensor is not limited thereto. For example, the busbar may be configured as a U-shaped member in a side view which includes a pair of second portions protruding from two opposite end edges of a first portion. Also, in the case of the L-shaped busbar, the magnetic flux concentrating plate may be positioned at any location of the first portion along the busbar longitudinal direction. However, magnetic saturation of the magnetic flux concentrating plate 12 may be further suppressed by positioning the magnetic flux concentrating plate 12 in the vicinity of the one end edge 111a of the first portion 111 of the L-shaped busbar 11 from which the second portion 112 protrudes, as described above.

Moreover, as an example of the current sensor, the above-described embodiment shows the current sensor 1 including the magnetic flux concentrating plate 12, wherein the magnetic flux concentrating plate 12 is positioned closer to the one end edge 111a than the middle of the first portion 111 of the L-shaped busbar 11. However, the current sensor is not limited thereto. Also, in the case of the L-shaped busbar, the magnetic flux concentrating plate may be positioned at the first portion, for example in the middle thereof. However, magnetic saturation of the magnetic flux concentrating plate 12 may be still further suppressed by positioning the magnetic flux concentrating plate 12 closer to the one end edge 111a than the middle of the first portion 111, as described above.

Furthermore, as an example of the C-shaped magnetic flux concentrating plate, the above-described embodiment shows the magnetic flux concentrating plate 12 including the bottom plate section 121, the pair of arm plate sections 122, and the pair of top plate sections 123. However, the C-shaped magnetic flux concentrating plate is not limited thereto, but may be e.g. formed in a C-shape from a hollow cylinder with a partially cut-out circumferential wall. However, an increase of the size of the magnetic flux concentrating plate 12 may be further suppressed by its configuration with the bottom plate section 121, the pair of arm plate sections 122, and the pair of top plate sections 123, as described above.

As an example of the current sensor, the above-described embodiment further shows the current sensor 1 including the Hall element 131, wherein the Hall element 131 is positioned in the vicinity of the opened portion 12a of the magnetic flux concentrating plate 12. However, the current sensor is not limited thereto, but the Hall element may be positioned at any location between the first portion of the busbar and the inner surface of the magnetic flux concentrating plate which allows magnetic flux for current measurement to be detected. However, the sensitivity for current measurement may be increased by positioning the Hall element 131 in the vicinity of the opened portion 12a of the magnetic flux concentrating plate 12, as described above.

### REFERENCE SIGNS LIST

1, 5 Current sensor

11, 61 Busbar

12 Magnetic flux concentrating plate

12a Opened portion

13 Sensor section

111 First portion

111a, 61a One end edge

111b Middle portion

111c Another end edge

112 Second portion

113 Through hole

121 Bottom plate section

122 Arm plate sections

123 Top plate sections

131 Hall element

132 Sensor board

D11 Direction of protrusion

D12 Busbar longitudinal direction

D13 Busbar width direction

D14 Concentrating plate longitudinal direction

G1, G2 Graph

L1 Solid line

L2 Dash-dotted line

L3 Dashed line

I Current

T11 Width direction

φ11, φ11a Magnetic flux

What is claimed is:

1. A current sensor comprising:
a busbar made of an electrically conductive metal and configured to allow a current from a measured object to flow therethrough,
wherein the busbar includes a first portion having a belt shape and a second portion,
wherein the second portion protrudes in a direction of protrusion from one end edge of the first portion, the direction of protrusion intersecting front and back faces of the first portion;
a magnetic flux concentrating plate made of a soft magnetic material,
wherein the magnetic flux concentrating plate has an orthogonal cross-section shape having a bent-plate shape surrounding, in a C-shape, a middle portion of the first portion of the busbar in a busbar longitudinal direction, the orthogonal cross-section shape extending orthogonally to the busbar longitudinal direction,
wherein the magnetic flux concentrating plate is configured to concentrate magnetic flux around the middle portion, the magnetic flux being generated due to a current which may flow through the busbar,
wherein an opened portion of the C-shape is opened in the direction of protrusion; and
a sensor section including a Hall element for current detection,
wherein the Hall element is positioned so as to be surrounded by the magnetic flux concentrating plate while being positioned between the opened portion and the middle portion so that the Hall element detects the current through the magnetic flux concentrated by the magnetic flux concentrating plate.

2. The current sensor according to claim 1,
wherein the busbar is formed only by the first portion and the second portion to form an L-shape in a side view of the busbar in an orthogonal direction, the orthogonal direction extending orthogonally to the direction of protrusion and the busbar longitudinal direction,
wherein the magnetic flux concentrating plate is positioned at the one end edge of the first portion and at a location of another end edge of the first portion opposite to the one end edge in the busbar longitudinal direction, the second portion protruding from the one end edge of the first portion, wherein the location is a location of another end edge which is closest to the one end edge.

3. The current sensor according to claim 2,
wherein the magnetic flux concentrating plate is positioned closer to the one end edge than a middle of the first portion in the busbar longitudinal direction.

4. The current sensor according to claim 1, wherein the magnetic flux concentrating plate includes:
a bottom plate section having a larger extension in a concentrating plate longitudinal direction than a width dimension of the first portion to face a face of front and back faces of the middle portion of the first portion opposite to a side of the middle portion with the Hall element positioned thereon, the concentrating plate longitudinal direction extending along a busbar width direction of the first portion;
a pair of arm plate sections protruding in the direction of protrusion of the second portion from two opposite end edges of the bottom plate section in the concentrating plate longitudinal direction; and
a pair of top plate sections each extending along the concentrating plate longitudinal direction from one of protrusion end edges of the pair of arm plate sections so as to face a face of the middle portion with the Hall element positioned thereon, wherein extension end edges of the pair of top plate sections is spaced from each other to form the opened portion together.

5. The current sensor according to claim 1,
wherein the Hall element is positioned at a location of the magnetic flux concentrating plate which is closer to the opened portion than the first portion in the direction of protrusion.
